(19) United States
(12) Patent Application Publication
(10) Pub. No.: US 2025/0300090 A1
(43) Pub. Date: Sep. 25, 2025

(54) ELECTRONIC DEVICE

(71) Applicant: STMicroelectronics International N.V., Geneva (CH)

(72) Inventors: Richard REMBERT, Quaix en Chartreuse (FR); Didier SIGNORET, Polienas (FR); Olivier FRANIATTE, Grenoble (FR)

(73) Assignee: STMicroelectronics International N.V., Geneva (CH)

(21) Appl. No.: 19/080,094

(22) Filed: Mar. 14, 2025

(30) Foreign Application Priority Data
Mar. 21, 2024 (FR) FR2402805

(51) Int. Cl. H01L 23/544; H01L 21/60; H01L 23/00; H01L 23/498

(52) U.S. Cl. CPC H01L 23/544; H01L 21/60; H01L 23/49816; H01L 23/49827; H01L 24/32; H01L 24/48; H01L 24/73; H01L 2223/54426; H01L 2224/32225; H01L 2224/48235; H01L 2224/73215

(57) ABSTRACT

An electronic device includes an interconnection substrate having, on the side of an upper connection surface, an electrically-insulating protective layer. The electrically-insulating protective layer includes openings leaving accessible metallic electric connection areas intended to be welded or soldered to a connection element. A method of making the device includes a step of forming alignment marks on the surface of the electrically-insulating protective layer of the interconnection substrate, on the side of the upper surface of the electrically-insulating protective layer. The alignment marks made be formed, for example, by the depositing of a marking material which forms the marks.

### PRIORITY CLAIM

This application claims the priority benefit of French Application for Patent No. 2402805, filed on Mar. 21, 2024, the content of which is hereby incorporated by reference in its entirety to the maximum extent allowable by law.

### TECHNICAL FIELD

The present disclosure generally concerns electronic devices and, more specifically, electronic chip packages.

### BACKGROUND

An electronic chip may be assembled in a package comprising an interconnection substrate, to which the chip is mechanically bonded and electrically connected. The assembly of the electronic chip to the interconnection substrate is assisted by an alignment tool, which uses alignment marks formed in the substrate to position the chip precisely in a predefined location.

It would be desirable to at least partly improve certain aspects of known electronic devices.

### SUMMARY

In an embodiment, a method is provided for manufacturing an electronic device comprising an interconnection substrate comprising, on the side of an upper connection surface, an electrically-insulating protective layer, the electrically-insulating protective layer comprising openings leaving accessible metallic electric connection areas intended to be welded or soldered to a connection element. The method comprises: depositing a marking material to form alignment marks at the surface of the electrically-insulating protective layer of the interconnection substrate, on the side of the upper surface of the electrically-insulating protective layer.

According to an embodiment, the alignment marks have a color which is golden or white.

According to an embodiment, the alignment marks have a dimension in the range from 150 μm to 500 μm.

According to an embodiment, the depositing of the marking material for the alignment marks comprises screen printing on top of and in contact with the electrically-insulating protective layer.

According to an embodiment, the alignment marks are adhesive and the depositing of the marking material for the alignment marks comprises transferring a support film, comprising on a lower surface side the alignment marks, onto the electrically-insulating protective layer and removing the support film while leaving at the surface of the electrically-insulating protective layer the alignment marks having adhered.

According to an embodiment, the marking material for the alignment marks is deposited on the surface of the electrically-insulating protective layer by collecting the alignment marks and then placing them on top of and in contact with the electrically-insulating protective layer.

According to an embodiment, the depositing of the marking material for forming the alignment marks comprises transferring a support film, inside and/or on top of which the alignment marks are formed, onto the electrically-insulating protective layer, the support film comprising openings enabling to leave the surface of the interconnection substrate freely accessible for an assembly of the connection element.

According to an embodiment, the method comprises mechanically bonding an electronic chip to the upper connection surface of the interconnection substrate.

According to an embodiment, the method comprises electrically connecting the electronic chip to the interconnection substrate via the metallic electric connection areas and the connection element.

According to an embodiment, during mechanically bonding the electronic chip, the electronic chip is aligned with the upper connection surface of the interconnection substrate by using the alignment marks.

According to an embodiment, the method comprises cutting the electronic device so as to obtain a plurality of electronic components, each electronic component comprising an electronic chip.

Another embodiment provides an electronic device comprising: an interconnection substrate comprising, on the side of an upper connection surface, an electrically-insulating protective layer, the electrically-insulating protective layer comprising openings leaving accessible metallic electric connection pads intended to be welded or soldered to a connection element; and alignment marks formed on the surface of the electrically-insulating protective layer, on the side of the upper surface of the electrically-insulating protective layer.

According to an embodiment, the device comprises an electronic chip bonded to the upper connection surface of the interconnection substrate and electrically connected to the interconnection substrate via the metallic electric connection pads and the connection element.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A, FIG. 1B, and FIG. 1C are views, partial and simplified, of an example of an electronic device;

FIG. 2A to 2B, and FIGS. 3A to 3B are views illustrating steps of an example of a method of manufacturing the electronic device of FIGS. 1A, 1B, and 1C;

FIGS. 4A to 4B, FIGS. 5A to 5B, and FIGS. 6A to 6B are views illustrating steps of another example of a method of manufacturing the electronic device of FIGS. 1A, 1B, and 1C;

FIGS. 7A to 7B, FIG. 8, and FIGS. 9A to 9B are views illustrating steps of still another example of a method of manufacturing the electronic device of FIGS. 1A, 1B, and 1C; and

FIGS. 10A to 10B, FIGS. 11A to 11B, and FIGS. 12A to 12B are views illustrating steps of still another example of a method of manufacturing the electronic device of FIGS. 1A, 1B, and 1C.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the interconnection substrate and its manufacturing have not been detailed. Further, the electronic chip and its manufacturing have not been detailed, the described embodiments being compatible with all electronic chips.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

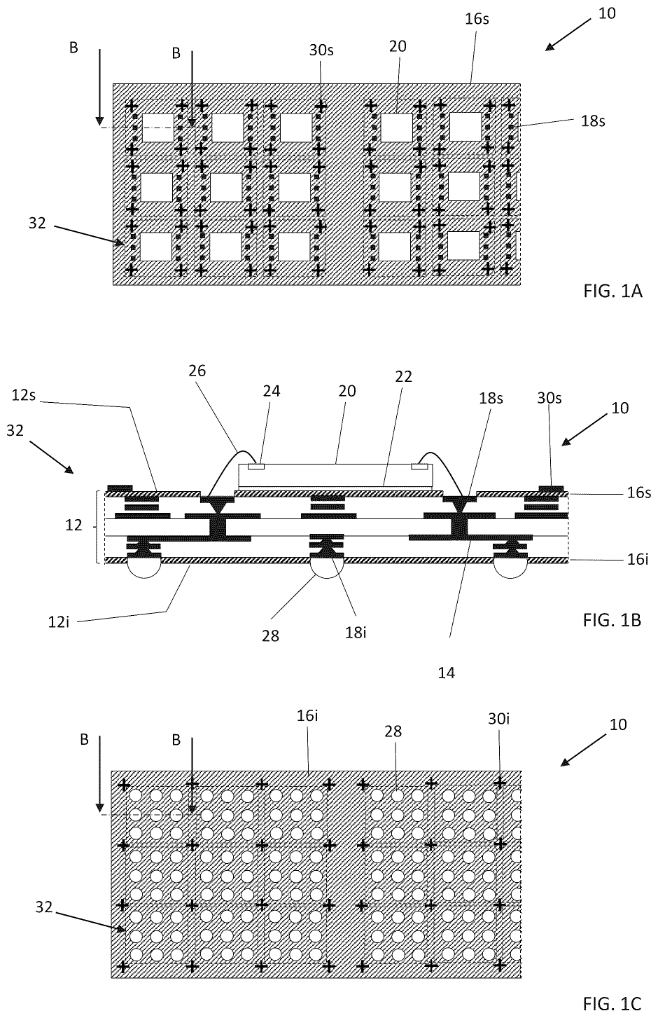

FIG. 1A, FIG. 1B, and FIG. 1C are views, partial and simplified, of an example of an electronic device 10.

More specifically, FIG. 1A is a top view of electronic device 10, FIG. 1B is a cross-section view of electronic device 10, and FIG. 1C is a bottom view of electronic device 10, FIG. 1B being a view along the cross-section plane BB of FIGS. 1A and 1C.

Electronic device 10 comprises an interconnection substrate 12. Substrate 12 comprises an upper connection surface 12s and a lower connection surface 12i, opposite to upper connection surface 12s. These two surfaces are, for example, substantially planar. As an example, substrate 12 comprises a polymer material, for example a resin, for example of epoxy type. As an example, substrate 12 further comprises fiberglass, mixed with the polymer material.

Substrate 12 has, for example, a rectangular shape. Substrate 12 has, for example, dimensions in the range from 30 mm by 10 mm to 800 mm by 150 mm, for example in the range from 100 mm by 40 mm to 400 mm by 70 mm, for example in the order of 216 mm by 58 mm.

Substrate 12 comprises, for example, electric conductors 14 running through the polymer material and electrically coupling the upper surface 12s to the lower face 12i of substrate 12. As an example, electric conductors 14 comprise metal levels corresponding to horizontal conductive tracks (in the orientation of FIG. 1B) and vertical conductive vias. For example, the electric conductors 14 of substrate 12 are made of copper.

Substrate 12 comprises, for example, on the side of its lower 12i and upper 12s surfaces, electrically-insulating protective layers 16. Substrate 12 thus comprises a protective layer 16i flush with its lower surface 12i and another electrically-insulating protective layer 16s flush with its upper surface 12s.

Protective layers 16, also known as solder masks, are layers enabling to protect the upper metal levels of electric conductors 14 from oxidation. Protective layers 16 extend, for example, over the entire surface of substrate 12. Protective layers 16 are, for example, locally open, leaving conductive electric connection areas 18 accessible.

As an example, electric connection pads 18i are present on the side of the lower surface 12i of substrate 12. Similarly, other electric connection areas 18s are present on the side of the upper surface 12s of substrate 12.

Electric connection pads 18 are, for example, electrically connected to the electric conductors 14 of substrate 12. The connection pads 18s of the upper surface 12s of substrate 12 are thus electrically connected to the connection pads 18i of the lower surface 12i of substrate 12. Electric connection pads 18 are, for example, made of metal, for example made of gold.

Conductive areas 18s, for example, enable to electrically connect at least one external element, for example an electronic chip, to the upper surface 12s of substrate 12.

An electronic chip 20 is, for example, bonded to substrate 12 on the side of its upper surface 12s. As an example, chip 20 has, in top view, a substantially square shape. As a variant, chip 20 has, in top view, a round or rectangular shape. Chip 20 has dimensions, for example, in the range from 0.2 mm by 0.2 mm to 10 mm by 10 mm, for example from 0.5 mm by 0.5 mm to 5 mm by 5 mm, for example in the order of 1.5 mm by 1.5 mm.

Chip 20 is, for example, an integrated circuit (IC) chip. Chip 20 comprises, for example, a semiconductor substrate, for example made of silicon, inside and on top of which electronic components are formed.

Chip 20 is, for example, mechanically bonded to substrate 12, for example by means of a bonding layer 22. Bonding layer 22 corresponds, for example, to a layer of adhesive, for example an electrically-insulating adhesive. Bonding layer 22 extends, for example, under and in contact with the entire lower surface of chip 20.

Chip 20 is, for example, electrically connected to substrate 12. The electric connection between chip 20 and substrate 12 is, for example, performed by wire bonding between conductive areas 18s, formed on the upper surface 12s of substrate 12, and connection pads 24 of chip 20 located on the upper surface side of chip 20. As an example, connection pads 24 are flush with the upper surface of chip 20. As an example, pads 24 and areas 18s are connected by electric cables, or wires, 26. Wires 26 thus extend from the upper surface 12s of substrate 12 to the upper surface of chip 20. Wires 26 are, for example, made of gold, silver, or copper.

As an example, electronic device 10 is divided into a plurality of units 32, in line with the upper surface 12s of substrate 12, each unit 32 comprising a chip 20. Units 32 are, for example, all identical. As an example, FIG. 1B illustrates a portion of device 10 corresponding to a single unit 32 in cross-section view. In FIGS. 1A and 1C, units 32 have been delimited and shown by a dotted line. Each unit 32 has dimensions, for example, in the range from 1 mm by 1 mm to 30 mm by 30 mm, for example in the range from 3 mm by 3 mm to 10 mm by 10 mm, for example in the order of 6.5 mm by 6.5 mm.

Units 32 are, for example, organized in an array of rows and columns in device 10. In FIGS. 1A and 1C, fifteen units 32 have been fully shown and three have been partially shown. In practice, device 10 may comprise a number of units 32 larger than what has been shown.

Units 32 each correspond, for example, to an electronic component after their singulation. Each component is, for example, intended to be welded or soldered to an external device, not shown, for example a printed circuit board (PCB). As an example, substrate 12 is for example of BGA (Ball Grid Array) type, that is, the electric connection between the components and the external device is performed via solder balls 28 arranged on the lower surface 12i of substrate 12. As an example, balls 28 are arranged in regular rows and columns over all or part of the surface 12i of substrate 12. Balls 28 are, for example, made of a metallic material.

As an example, balls 28 are formed in contact with the areas 18i of the lower surface 12i of substrate 12.

Electronic device 10 further comprises alignment marks 30. Among the alignment marks 30, certain alignment marks 30s enable to ensure the alignment of chip 20, during its transfer, with the upper surface 12s of substrate 12. Alignment marks 30s are formed on the surface of protective layer 16s, on the upper surface side of protective layer 16s by the depositing of a marking material which forms the alignment marks. As an example, each alignment mark 30s is associated with a single unit 32. Each unit 32 comprises, on the side of the upper surface 12s of substrate 12, a plurality of alignment marks 30s, for example four alignment marks 30s. As an example, each unit 32 comprises, at each of its corners, on the upper surface of protective layer 16s, an alignment mark 30s.

As an example, among the alignment marks 30, other alignment marks 30i enable to ensure the alignment of balls 28, as they are formed, on the lower surface 12i of substrate 12. Alignment marks 30i are formed at the surface of protective layer 16i, on the lower surface side of protective layer 16i. As an example, alignment marks 30i are formed outside of units 32 and are, for example, associated with a plurality of adjacent units 32. As an example, each unit 32 is associated with a plurality of alignment marks 30i, for example four alignment marks 30i.

As an example, alignment marks 30 are made of a deposited marking material having, with protective layer 16, a contrast enabling an alignment tool to detect the alignment marks 30 on protective layer 16.

As an example, alignment marks 30 have a color which is golden. As a variant, alignment marks 30 have a color which is white.

In FIGS. 1A and 1B, alignment marks 30 have the shape of a cross. As a variant, alignment marks 30 may have a different shape, for example a round shape, a square shape, a triangular shape, or a rectangular shape. Alignment marks 30 have, for example a dimension in the range from 150 μm to 500 μm.

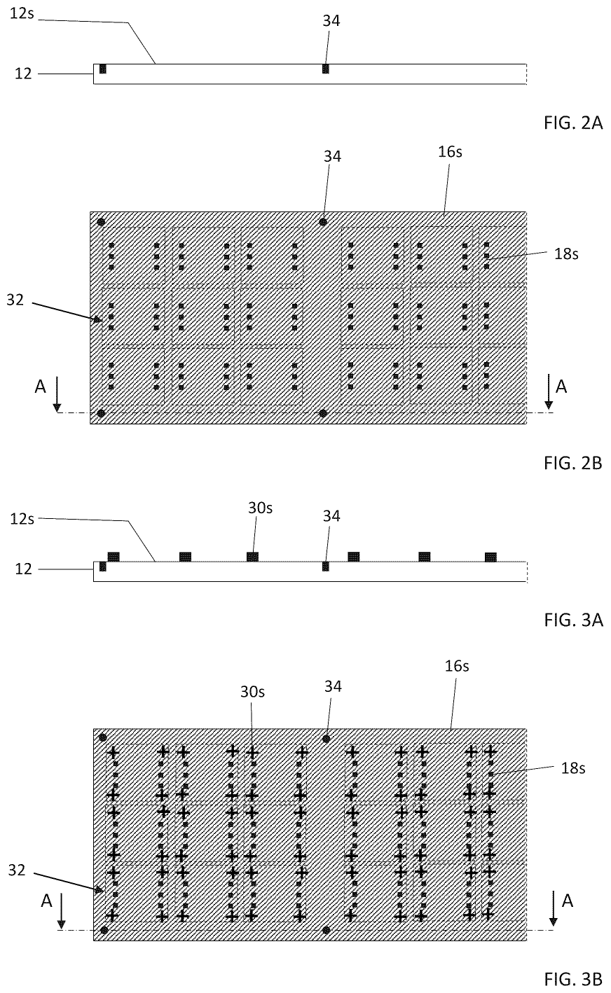

FIGS. 2A to 2B, and FIGS. 3A to 3B are views illustrating steps of an example of a method of manufacturing the electronic device 10 of FIGS. 1A, 1B, and 1C.

More specifically, FIGS. 2A and 3A are cross-section views and FIGS. 2B and 3B are top views illustrating steps of an example of a method of manufacturing the electronic device 10 of FIGS. 1A, 1B, and 1C, FIG. 2A being a view along the cross-section plane AA of FIG. 2B and FIG. 3A being a view along the cross-section plane AA of FIG. 3B.

During the steps of FIGS. 2A, 2B, 3A, and 3B, it is provided to form alignment marks 30s by screen printing the marking material on the upper surface 12s of substrate 12.

FIGS. 2A and 2B illustrate an initial structure corresponding to interconnection substrate 12 comprising electric conductors 14, pads 18, and protective layers 16. In FIG. 2A, substrate 12 is schematically represented by a white rectangle, without for electrical conductors 14, protective layer 16, and areas 18 to be shown.

The structure illustrated in FIGS. 2A and 2B further comprises other alignment marks 34. Alignment marks 34 enable to ensure the correct positioning of alignment marks 30s on the upper surface 12s of substrate 12. In other words, alignment marks 34 correspond to the marks for aligning alignment marks 30s.

Alignment marks 34 are, for example, formed in substrate 12. Alignment marks 34 extend, for example, across only part of the thickness of substrate 12.

As an example, alignment marks 34 are formed in the same metal level as connection areas 18s. Alignment marks 34 are formed, for example, at the same time as areas 18s. Alignment marks 34 are, for example, made of gold.

As a variant, alignment marks 34 are formed in the same level as one of the conductive tracks of electric conductors 14, for example the same metal level as the last track (that is, the highest track) of electric conductors 14. Alignment marks 34 are flush with, for example, the upper surface 12s of the interconnection network of substrate 12. Alignment marks 34 are, for example, formed at the same time as one of the tracks of electric conductors 14. Alignment marks 34 are, for example, made of copper.

Alignment marks 34 are formed prior to the forming of protective layer 16s. The alignment marks are, for example, covered by protective layer 16s. As a variant, it may be provided for layer 16s to be open opposite all or part of alignment marks 34, alignment marks 34 are then not covered or only partially covered by protective layer 16s. As an example, when alignment marks 34 are at least partly covered by layer 16s, they are in contact, by their upper surfaces, with the lower surface of protective layer 16s.

Alignment marks 34 are, for example, distributed over the entire surface of the device 10 and are, for example, formed outside of units 32.

FIGS. 3A and 3B illustrate a structure obtained at the end of a step of screen printing of alignment marks 30s on the upper surface of the structure illustrated in FIG. 2A.

During this step, alignment marks 30s are formed by screen printing on top of and in contact with the upper surface of protective layer 16s. This step is, for example, assisted by an alignment tool so that the position of alignment marks 30s on the surface of layer 16 is defined with respect to the position of alignment marks 34.

As an example, alignment marks 30s are formed by local deposition of an ink as the marking material. As an example, the ink is gold-colored. As an example, the ink comprises a golden pigment. The ink comprises, by weight, for example between 1% and 30% of golden pigment, for example between 10% and 20% of golden pigment, for example in the order of 8% of golden pigment. As a variant, the ink has a color which is white.

At the end of the step of forming of alignment marks 30s, the electronic chips 20 are, for example, transferred to the upper surface of protective layer 16s by using alignment marks 30s.

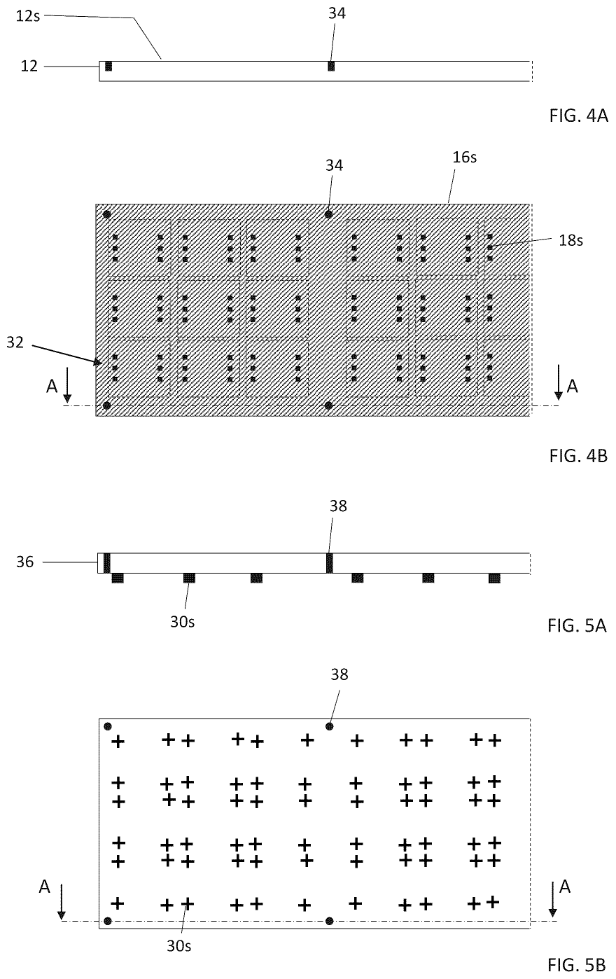

FIGS. 4A to 4B, FIGS. 5A to 5B, and FIGS. 6A to 6B are views illustrating steps of another example of a method of manufacturing the electronic device 10 of FIGS. 1A, 1B, and 1C.

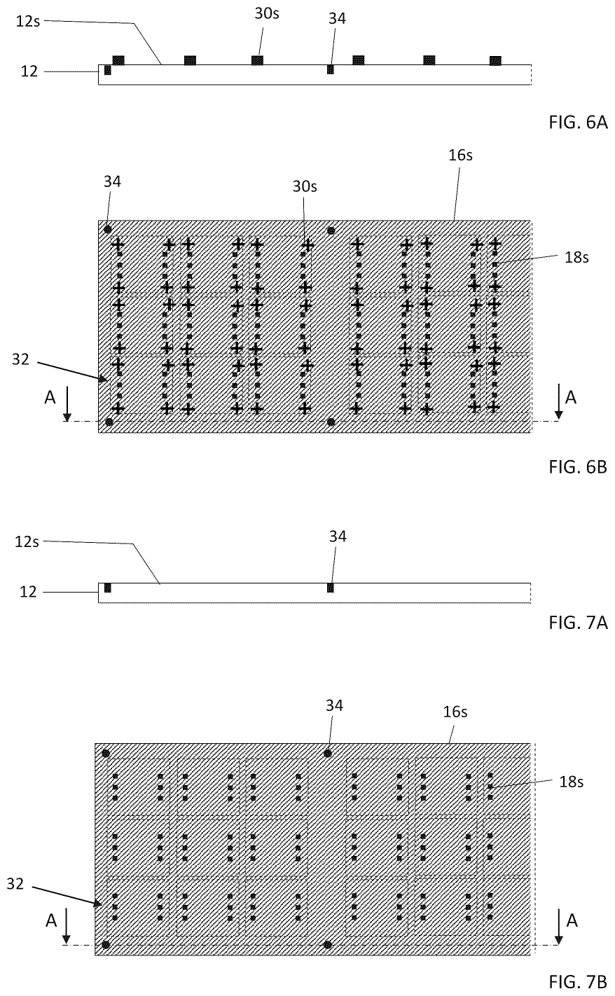

More particularly, FIGS. 4A, 5A, and 6A are cross-section views and FIGS. 4B, 5B, and 6B are top views illustrating steps of another example of a method of manufacturing the electronic device 10 of FIGS. 1A, 1B, and 1C, FIG. 4A being a view along the cross-section plane AA of FIG. 4B, FIG. 5A being a view along the cross-section plane AA of FIG. 5B, and FIG. 6A being a view along the cross-section plane AA of FIG. 6B.

During the steps of FIGS. 4A, 4B, 5A, 5B, 6A, and 6B, alignment marks 30s are formed by self-adhesive decal as the marking material, that is, by transfer of the adhesive alignment marks 30s from a support film 36 onto interconnection substrate 12.

FIGS. 4A and 4B illustrate a structure identical to the structure illustrated in FIGS. 2A and 2B.

FIGS. 5A and 5B illustrate a support film 36 at the surface of which alignment marks 30s are formed. Alignment marks 30s are, in FIG. 5A, formed on the lower surface of support film 36. As an example, alignment marks 30s have an adhesive lower surface.

Support film 36 comprises, for example, alignment marks 38, which enable, together with alignment marks 34, to ensure the correct positioning of alignment marks 30s. Alignment marks 38 for example enable, in a subsequent step, to position and to align support film 36 on the structure illustrated in FIGS. 4A and 4B by having the alignment marks 38 of support film 36 coincide in top view with the alignment marks 34 of the structure illustrated in FIGS. 4A and 4B.

As an example, alignment marks 38 are formed in support film 36. As a variant, alignment marks 38 are formed at the surface of support film 36, in contact with the lower surface of support film 36 or in contact with the upper surface of support film 36.

Alignment marks 38 are, for example, formed by screen printing or by etching. Alignment marks 38 have, for example, a color which is golden or white.

Support film 36 is made of a polymer material, for example made of epoxy.

FIGS. 6A and 6B illustrate a structure obtained at the end of a step of transfer of support film 36 onto the structure illustrated in FIGS. 2A and 2B. More precisely, during this step, the lower surface of the structure illustrated in FIG. 4A is brought into contact with the upper surface of the structure illustrated in FIG. 5A. Even more precisely, during this step, the two structures are transferred onto one another, by having coincide, in top view, alignment marks 34 and 38.

As an example, at the end of this transfer step, support film 36 is removed, leaving alignment marks 30s bonded by adhesion to the upper surface of protective layer 16s.

Similar to what has been described at the end of the steps of FIGS. 2A, 2B, 3A, and 3B, at the end of the removal of support film 36, for example, electronic chips 20 are transferred onto the upper surface of protective layer 16s by using alignment marks 30s.

FIGS. 7A to 7B, FIG. 8, and FIGS. 9A to 9B are views illustrating steps of still another example of a method of manufacturing the electronic device 10 of FIGS. 1A, 1B, and 1C.

More specifically, FIGS. 7A and 9A are cross-section views and FIGS. 7B, 8, and 9B are top views illustrating steps of still another example of a method of manufacturing the electronic device 10 of FIGS. 1A, 1B, and 1C, FIG. 7A being a view along the cross-section plane AA of FIG. 7B and FIG. 9A being a view along the cross-section plane AA of FIG. 9B.

During the steps of FIGS. 7A, 7B, 8, 9A, and 9B, alignment marks 30s are formed by collecting alignment marks 30s made of the marking material from a band 39 and then placing them on the upper surface 12s of interconnection substrate 12.

FIGS. 7A and 7B illustrate a structure identical to the structure illustrated in FIGS. 2A and 2B.

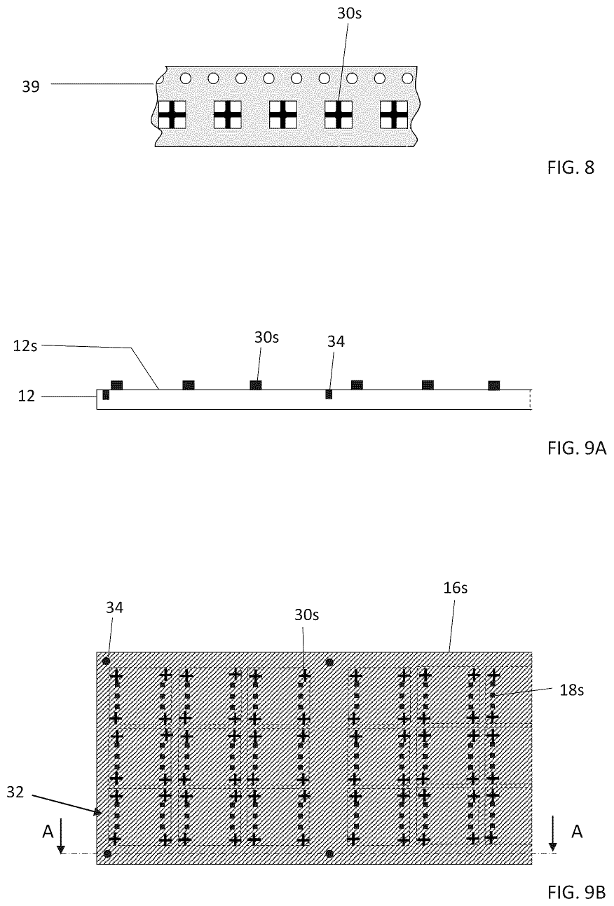

FIG. 8 shows a band 39, for example a band from a reel, having alignment marks 30s formed therein. Alignment marks 30s are, for example, arranged on band 39 in a line and are, for example, evenly spaced apart. As an example, the band is made of an adhesive material so that alignment marks 30s are stuck to band 39.

FIGS. 9A and 9B illustrate a structure obtained at the end of a step of transfer of the alignment marks 30s present on the band 39 of FIG. 8, onto the upper surface 12s of the substrate 12 of the structure illustrated in FIG. 7A.

During this step, alignment marks 30s are, for example, collected from the band 39 illustrated in FIG. 8 and then placed on the upper surface 12s of substrate 12 and, more particularly, the upper surface of protective layer 16s. This step is, for example, assisted by an alignment tool enabling to position alignment marks 30s by using alignment marks 34.

Once all alignment marks 30s have been placed on the upper surface 12s of substrate 12, and similarly to the steps described in FIGS. 2A, 2B, 3A, and 3B, the electronic chips 20, for example, are transferred onto the upper surface 12s of substrate 12, so as to form the device 10 illustrated in FIGS. 1A to 1C, by using alignment marks 30s.

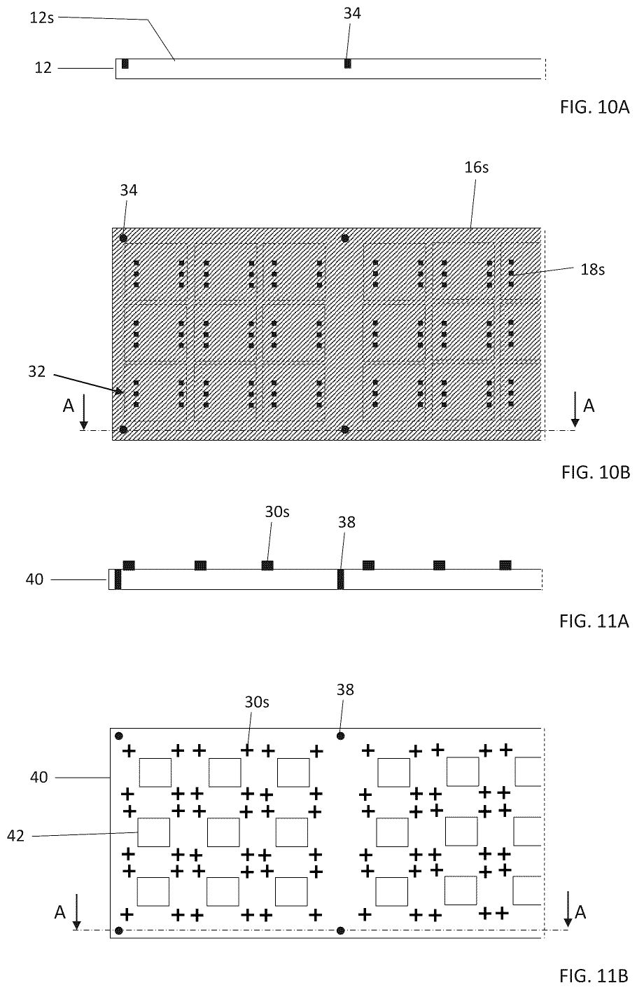

FIGS. 10A to 10B, FIGS. 11A to 11B, and FIGS. 12A to 12B are views illustrating steps of still another example of a method of manufacturing the electronic device 10 of FIGS. 1A, 1B, and 1C.

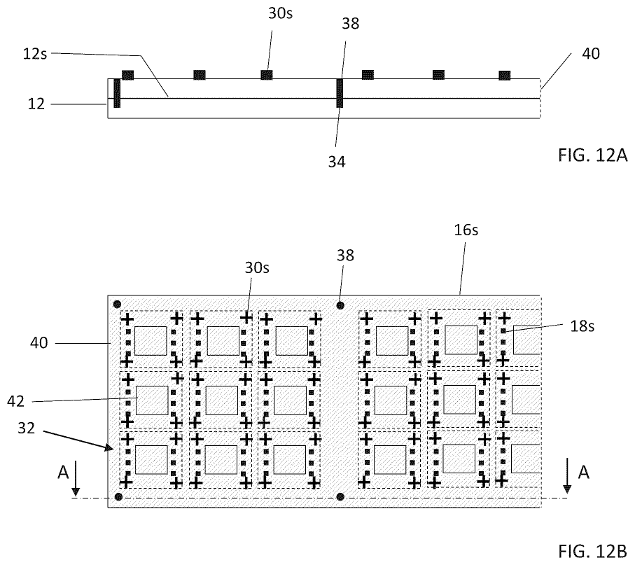

More specifically, FIGS. 10A, 11A, and 12A are cross-section views and FIGS. 10B, 11B, and 12B are top views illustrating steps of another example of a method of manufacturing the electronic device 10 of FIGS. 1A, 1B, and 1C, FIG. 10A being a view along the cross-section plane AA of FIG. 10B, FIG. 11A being a view along the cross-section plane AA of FIG. 11B, and FIG. 12A being a view along the cross-section plane AA of FIG. 12B.

During the steps of FIGS. 10A, 10B, 11A, 11B, 12A, and 12B, it is provided to form alignment marks 30s on a support film 40, and then to transfer support film 40 onto the upper surface 12s of substrate 12.

FIGS. 10A and 10B illustrate a structure identical to the structure illustrated in FIGS. 2A and 2B.

FIGS. 11A and 11B illustrate a structure comprising a support film 40, over and/or inside of which alignment marks 30s are formed.

As an example, alignment marks 30s are formed in support film 40. Alignment marks 30s are, for example, formed by etching. As an example, after the etch step, alignment marks 30s appear during a step of deposition, in the etched patterns, of a material having the colorimetric properties mentioned in relation with FIGS. 1A to 1C.

As a variant, alignment marks 30s are formed over and in contact with the upper surface of support film 40. Alignment marks 30s are formed by screen printing, for example.

Support film 40 is, for example, made of a polymer material, for example of epoxy.

The structure illustrated in FIGS. 11A and 11B further comprises other alignment marks, similar to the alignment marks 38 illustrated in FIGS. 5A and 5B. Alignment marks 38 for example enable, in a subsequent step, to position and to align support film 40 on the structure illustrated in FIGS. 10A and 10B by having the alignment marks 38 of support film 40 coincide top view with the alignment marks 34 of the structure illustrated in FIGS. 10A and 10B.

The structure illustrated in FIGS. 11A and 11B further comprises openings 42 thoroughly crossing support film 40, from its upper surface to its lower face. Openings 42 are, for example, homogeneously distributed throughout the support film. As an example, openings 42 are larger than the size of the electronic chips 20 which will be subsequently transferred onto the upper surface 12s of substrate 12.

FIGS. 12A and 12B illustrate a structure obtained at the end of a step of transfer of the structure illustrated in FIGS. 11A and 11B onto the structure illustrated in FIGS. 10A and 10B. More specifically, during this step, the lower surface of the structure illustrated in FIG. 10A is brought into contact with the upper surface of the structure illustrated in FIG. 11A. Even more specifically, during this step, the two structures are transferred onto one another, by having coincide, in top view, alignment marks 34 and 38.

At the end of this step, alignment marks 30s are thus separated from the upper surface 12s of substrate 12 by all or part of the thickness of support film 40.

At the end of the step of transfer of support film 40 onto the structure illustrated in FIGS. 10A and 10B, and similarly to what has been described at the end of the steps of FIGS. 2A, 2B, 3A, and 3B, electronic chips 20 are, for example, mechanically bonded to the upper surface 12s of substrate 12, by using alignment marks 30s. Chips 20 are then electrically connected to substrate 12, so as to form the device 10 illustrated in FIGS. 1A to 1C. During the step of bonding of chips 20, the chips are, for example, bonded to the upper surface 12s of substrate 12, through support film 40 via openings 42. Openings 42 are aligned, for example, in front of the locations of the chips 20 on the upper surface 12s of substrate 12. Openings 42 are then sufficiently large for film 40 not to cover pads 18s. As an example, each opening 42 is larger, in top view, than the association of a chip 20 and of the areas 18s to which the chip is connected.

As an example, after the mechanical bonding of chips 20 to the upper surface 12s of substrate 12, support film 40 is removed. The support film is, for example, removed between the step of mechanical bonding of chips 20 to substrate 12 and the step of electric connection of chips 20 to substrate 12. As a variant, support film 40 is removed after the step of electric connection of chips 20 to substrate 12.

After the cutting of the units 32 of device 10 so as to form individual components, these electronic components have applications in many industrial fields and, in particular, in the automotive field, in the communications field, or in the field of connected wearables. For example, such components may be used in microelectromechanical systems, in sensors, or in microcontrollers.

An advantage of the present embodiment is that it enables to displace alignment marks 30s, usually formed in one of the upper levels of the electric conductors, onto the upper surface of protective layer 16.

Another advantage of the present embodiment is that it enables to decrease the metal bulk in the upper levels of the electric conductors.

Still another advantage of the present embodiment is that it enables to decrease the surface area of interconnection substrate 12.

Still another advantage of the present embodiment is that it enables to laterally extend the tracks of the upper levels of the electrical conductors.

Those skilled in the art will understand that certain features of these various embodiments and variants may be combined, and other variants will occur to those skilled in the art.

In particular, although only the forming of alignment marks 30s has been described herein, alignment marks 30i may be formed at the surface of the lower side of protective layer 16i by the same methods.

Further, although an embodiment in which chip 20 is electrically connected to interconnection substrate 12 by conductive wires linking the electric connection pads 24 formed on the side of the upper surface of the chip to electric connection pads 18 formed on the side of the upper surface 12s of substrate 12 has been described, the described embodiments are not limited to this specific case. As a variant, chip 20 may be connected to the substrate by conductive balls coupling lower connection pads of the chip to electric connection pads on the side of the upper surface 12s of substrate 12 below chip 20.

Finally, the practical implementation of the described embodiments and variants is within the abilities of those skilled in the art based on the functional indications given hereabove.

1. A method of manufacturing an electronic device, where the electronic device comprises an interconnection substrate having, on a side of an upper connection surface, an electrically-insulating protective layer, wherein the electrically-insulating protective layer includes openings leaving accessible metallic electric connection areas intended to be welded or soldered to a connection element, the method comprising:
depositing a marking material on the surface of the electrically-insulating protective layer of the interconnection substrate to provide alignment marks, said alignment marks located on a side of an upper surface of the electrically-insulating protective layer.

2. The method according to claim 1, wherein the alignment marks have a color which is golden or white.

3. The method according to claim 1, wherein the alignment marks have a dimension in a range from 150 μm to 500 μm.

4. The method according to claim 1, wherein depositing the marking material comprises screen printing the marking material on top of and in contact with the electrically-insulating protective layer.

5. The method according to claim 1, wherein the alignment marks are adhesive and wherein depositing the alignment marks comprises:
transferring a support film comprising, on a side of a lower surface thereof, the alignment marks onto the electrically-insulating protective layer; and
removing the support film while leaving the alignment marks adhered at the surface of the electrically-insulating protective layer.

6. The method according to claim 1, wherein depositing the alignment marks comprises: collecting the alignment marks and the placing the alignment marks on top of and in contact with the electrically-insulating protective layer.

7. The method according to claim 1, wherein depositing the alignment marks comprises: transferring a support film, inside and/or on top of which the alignment marks are formed, onto the electrically-insulating protective layer, wherein the support film comprises openings enabling to leave the surface of the interconnection substrate freely accessible for an assembly of the connection element.

8. The method according to claim 1, comprising mechanically bonding an electronic chip to the upper connection surface of the interconnection substrate.

9. The method according to claim 8, comprising electrically connecting the electronic chip to the interconnection substrate via the metallic electric connection areas and the connection element.

10. The method according to claim 8, wherein mechanically bonding the electronic chip comprises aligning the electronic chip with the upper connection surface of the interconnection substrate by using the alignment marks.

11. The method according to claim 8, comprising cutting the electronic device so as to obtain a plurality of electronic components, each electronic component comprising an electronic chip.

12. An electronic device, comprising:
an interconnection substrate comprising, on the side of an upper connection surface, an electrically-insulating protective layer, the electrically-insulating protective layer comprising openings leaving accessible metallic electric connection pads intended to be welded or soldered to a connection element; and
alignment marks deposited on the surface of the electrically-insulating protective layer, on the side of the upper surface of the electrically-insulating protective layer.

13. The electronic device according to claim 12, comprising an electronic chip bonded to the upper connection surface of the interconnection substrate and electrically connected to the interconnection substrate via the metallic electric connection pads and the connection element.

14. A method of manufacturing an electronic device, comprising:
providing an interconnection substrate having, on a side of an upper connection surface, an electrically-insulating protective layer, said electrically-insulating protective layer including openings through which metallic electric connection areas of the interconnection substrate are accessible;
forming alignment marks on an upper surface of the electrically-insulating protective layer, wherein forming comprises depositing a marking material on the upper surface of the electrically-insulating protective layer;
mounting an electronic chip through mechanical bonding to the interconnection substrate, wherein mounting includes aligning the electronic chip to the upper connection surface using the alignment marks on the upper surface of the electrically-insulating protective layer; and
electrically connecting the electronic chip to the interconnection substrate via the metallic electric connection areas.

15. The method according to claim 14, wherein depositing the marking material comprises screen printing the marking material on top of and in contact with the upper surface of the electrically-insulating protective layer.

16. The method according to claim 14, wherein depositing the marking material comprises:
transferring a support film comprising, on a side of a lower surface thereof, the alignment marks onto the electrically-insulating protective layer; and
removing the support film while leaving the alignment marks adhered at the surface of the electrically-insulating protective layer.

17. The method according to claim 14, wherein depositing the marking material comprises: collecting the alignment marks; and
placing the alignment marks on top of and in contact with the electrically-insulating protective layer.

18. The method according to claim 14 wherein depositing the marking material comprises:
transferring a support film, inside and/or on top of which the alignment marks are formed, onto the electrically-insulating protective layer, wherein the support film comprises openings at locations of the metallic electric connection areas.

19. The method according to claim 14, wherein the alignment marks have a color which is golden.

20. The method according to claim 14, wherein the alignment marks have a color which is white.
